(19) United States
(12) Patent Application Publication
(10) Pub. No.: US 2026/0288021 A1
(43) Pub. Date: Sep. 24, 2026

(54) CONDUCTIVE POLYMERS FOR RETICLE TABLE CLEANING APPARATUS

(71) Applicant: ASML Netherlands B.V., Veldhoven (NL)

(72) Inventors: Jungseung KIM, Trumbull, CT (US); Earl William EBERT, Oxford, CT (US)

(73) Assignee: ASML Netherlands B.V., Veldhoven (NL)

(21) Appl. No.: 19/167,984

(22) PCT Filed: Mar. 13, 2024
(86) PCT No.: PCT/EP2024/056738

§ 371 Date: Sep. 23, 2025

Related U.S. Application Data
(60) Provisional application No. 63/458,198, filed on Apr. 10, 2023.

(51) Int. Cl. G03F 7/00; B08B 6/00

(52) U.S. Cl. CPC G03F 7/70925; B08B 6/00; G03F 7/70708; G03F 7/70716; G03F 7/7095

(57) ABSTRACT

A reticle stage cleaning apparatus for a reticle stage clamp in a lithographic apparatus includes a substrate having a frontside and a backside opposite the frontside and a conductive layer disposed on the frontside of the substrate. The conductive layer is configured to contact the reticle stage clamp to dissipate charge on the reticle stage clamp and to remove particles on the reticle stage clamp via an electrostatic field generated between the conductive layer and the reticle stage clamp. The conductive layer can include a conductive polymer. The conductive polymer can have a conductivity of at least about 1 S/cm. The conductivity of the conductive polymer is variable and can be tuned to a desired value. The conductive polymer can include polyaniline, poly-p-phenylene, polythiophene, polypyrrole, poly-p-phenylene vinylene, trans-polyacetylene, a combination thereof, or a derivative thereof (e.g., polymer blends, copolymers, grafted polymers, surface modifications, surface treatments, additives, and/or fillers).

### CROSS-REFERENCE TO RELATED APPLICATION

This application claims priority of a US application U.S. 63/458,198 which was filed on 10 April 2023, and which is incorporated herein in its entirety by reference.

### FIELD

The present disclosure relates to reticle table cleaning (RTC) apparatuses, systems, and methods, for example, charge dissipative and particle removing RTC apparatuses for lithographic apparatuses and systems.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern of a patterning device (e.g., a mask, a reticle) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, deep ultraviolet (DUV) radiation with a wavelength of 157 nm or 193 nm or 248 nm.

A reticle stage used in a lithographic apparatus to hold a patterning device can become contaminated over time (e.g., accumulate particles). The contamination can be transferred from the reticle stage to the patterning device, for example, by an electrostatic clamp that holds the patterning device during patterning. The contamination can accumulate on the patterning device and cause patterning errors and/or defects. A contaminated reticle stage can be manually cleaned, but manual cleaning can leave a residue of fine particles. Further, manual cleaning requires the lithographic apparatus be vented to atmospheric pressure and partially disassembled, reducing overall yield.

Current RTC devices use an insulating top coating that can accumulate charge over multiple cycles (e.g., trapping of charge carriers in insulating coating). Under vacuum, RTC devices can eventually stick to the reticle stage due to parasitic charge between opposing insulating contact surfaces. Parasitic charge requires that the lithographic apparatus be vented to atmospheric pressure and partially dissembled in order to manually separate the RTC device from the reticle stage. One way to dissipate charge between the reticle stage (e.g., the electrostatic clamp) and an RTC device is to use a separate conductive device disposed between each load of the RTC device. However, this process slows scanning ability and overall efficiency of the lithographic apparatus since two devices are needed.

### SUMMARY

Accordingly, there is a need to dissipate charge on the reticle stage, remove particles from the reticle stage, and increase efficiency, scanning ability, and overall yield in the lithographic apparatus with a single conductive RTC device.

In some aspects, a reticle stage cleaning apparatus for a reticle stage clamp in a lithographic apparatus can include a substrate having a frontside and a backside opposite the frontside. In some aspects, the reticle stage cleaning apparatus can include a conductive layer disposed on the frontside of the substrate. In some aspects, the conductive layer can be configured to contact the reticle stage clamp to dissipate charge on the reticle stage clamp. In some aspects, the conductive layer can be configured to remove particles on the reticle stage clamp via an electrostatic field generated between the conductive layer and the reticle stage clamp.

In some aspects, a conductivity of the conductive layer can be at least about 1 S/cm. In some aspects, a conductivity of the conductive layer can be greater than about 1 S/cm. In some aspects, a conductivity of the conductive layer can be at least about 2 S/cm. In some aspects, a conductivity of the conductive layer can be at least about 5 S/cm. In some aspects, a conductivity of the conductive layer can be at least about 10 S/cm. In some aspects, a conductivity of the conductive layer can be at least about 100 S/cm. In some aspects, a conductivity of the conductive layer can be at least about 200 S/cm.

In some aspects, a conductivity of the conductive layer can be in a range between about 1 S/cm to about 600 S/cm. In some aspects, a conductivity of the conductive layer can be in a range between about 10 S/cm to about 600 S/cm. In some aspects, a conductivity of the conductive layer can be in a range between about 100 S/cm to about 600 S/cm. In some aspects, a conductivity of the conductive layer can be in a range between about 100 S/cm to about 1000 S/cm.

In some aspects, a conductivity of the conductive layer can be variable and can be configured to be tuned to a desired value.

In some aspects, the conductive layer can include a conductive polymer. In some aspects, the conductive polymer can include polyaniline, poly-p-phenylene, polythiophene, polypyrrole, poly-p-phenylene vinylene, trans-polyacetylene, or a combination thereof. In some aspects, a combination of polyaniline, poly-p-phenylene, polythiophene, polypyrrole, poly-p-phenylene vinylene, and/or trans-polyacetylene can include polymer blends, copolymers, and/or grafted polymers.

In some aspects, the conductive polymer can include an additive. In some aspects, the additive can be configured to modify a conductivity of the conductive polymer. In some aspects, the additive can be configured to modify a mechanical property of the conductive polymer. In some aspects, the additive can include carbon, graphite, carbon black, carbon nanotubes, carbon fullerenes, metal particles, plasticizers, flame retardants, heat stabilizers, impact modifiers, antioxidants, colorants, lubricants, light stabilizers, quenchers, acid scavengers, pigments, antistatic agents, nucleating agents, tribological, slip compounds, or a combination thereof.

In some aspects, the conductive polymer can include a filler. In some aspects, the filler can be configured to modify a conductivity of the conductive polymer. In some aspects, the filler can be configured to modify a mechanical property of the conductive polymer. In some aspects, the filler can include an organic material, an inorganic material, a polymeric material, a metallic material, a ceramic material, or a combination thereof. In some aspects, the filler can include carbon, graphite, carbon black, carbon nanotubes, carbon fullerenes, metal particles, wood, fiber, glass fiber, carbon fiber, minerals, calcium carbonate, clay, kaolin, titanium dioxide, talc, wollastonite, glass, mica, aluminum trihydrate, nanofillers, or a combination thereof.

In some aspects, the conductive polymer can include a single layer. In some aspects, the conductive polymer can include a plurality of layers. In some aspects, the conductive polymer can include a surface treatment (e.g., surface roughening, surface abrasion, plasma treatment, acid treatment, etc.). In some aspects, the conductive polymer can include a surface modification (e.g., graft polymerization, corona treatment, etc.).

In some aspects, the reticle stage cleaning apparatus can further include a second conductive layer disposed between the conductive layer and the substrate. In some aspects, a stiffness of the conductive layer can be lower than a stiffness of the second conductive layer. In some aspects, a conductivity of the second conductive layer can be in a range of about 50 S/cm to about 850 S/cm. In some aspects, the second conductive layer can include chromium nitride, titanium nitride, or carbon nitride. In some aspects, a conductivity of the conductive layer can be variable and can be configured to compensate for a conductivity of the second conductive layer such that a total conductivity of the apparatus can be tuned to a desired value.

In some aspects, a lithographic apparatus can include the reticle stage cleaning apparatus. In some aspects, a metrology apparatus can include the reticle stage cleaning apparatus.

In some aspects, a lithographic apparatus can include an illumination system configured to illuminate a patterning device. In some aspects, the lithographic apparatus can include a projection system configured to project an image of the patterning device onto a patterning substrate. In some aspects, the lithographic apparatus can include a reticle stage configured to support the patterning device. In some aspects, the reticle stage can include a chuck and an electrostatic clamp. In some aspects, the electrostatic clamp can include a plurality of burls. In some aspects, the lithographic apparatus can include a reticle stage cleaning apparatus configured to dissipate charge on the electrostatic clamp and to remove particles on the electrostatic clamp. In some aspects, the reticle stage cleaning apparatus can include a substrate having a frontside and a backside opposite the frontside. In some aspects, the reticle stage cleaning apparatus can include a conductive layer disposed on the frontside of the substrate. In some aspects, the conductive layer can be configured to contact the plurality of burls of the electrostatic clamp. In some aspects, the conductive layer can be configured to remove particles on the electrostatic clamp via an electrostatic field generated between the conductive layer and the electrostatic clamp.

In some aspects, a conductivity of the conductive layer can be at least about 1 S/cm. In some aspects, a conductivity of the conductive layer can be at least about 10 S/cm. In some aspects, a conductivity of the conductive layer can be in a range between about 10 S/cm to about 600 S/cm. In some aspects, a conductivity of the conductive layer can be in a range between about 10 S/cm to about 1000 S/cm.

In some aspects, the conductive layer can include a conductive polymer. In some aspects, the conductive polymer can include polyaniline, poly-p-phenylene, polythiophene, polypyrrole, poly-p-phenylene vinylene, trans-polyacetylene, or a combination thereof. In some aspects, the conductive polymer can be polyaniline. In some aspects, the conductive polymer can be poly-p-phenylene. In some aspects, the conductive polymer can be polythiophene. In some aspects, the conductive polymer can be polypyrrole. In some aspects, the conductive polymer can be poly-p-phenylene vinylene. In some aspects, the conductive polymer can be trans-polyacetylene.

In some aspects, a method of forming a reticle stage cleaning apparatus for removing particles on a reticle stage in a lithographic apparatus can include forming a conductive polymer on a frontside of a substrate with a conductivity of at least about 1 S/cm. In some aspects, the conductivity can be at least about 10 S/cm. In some aspects, the conductivity can be in a range between about 10 S/cm to about 600 S/cm. In some aspects, the conductive polymer can include polyaniline, poly-p-phenylene, polythiophene, polypyrrole, poly-p-phenylene vinylene, trans-polyacetylene, or a combination thereof.

In some aspects, forming the conductive polymer can include tuning the conductivity of the conductive polymer to a desired value. In some aspects, tuning the conductivity can include using polymerization. In some aspects, tuning the conductivity can include including an additive in the conductive polymer. In some aspects, tuning the conductivity can include including a filler in the conductive polymer.

In some aspects, forming the conductive polymer can include spin coating, slit coating, dip coating, spray coating, electrospinning, deposition, gravure coating, or a combination thereof. In some aspects, forming the conductive polymer can include forming a plurality of layers.

In some aspects, the method can further include forming a conductive layer disposed between the conductive polymer and the substrate. In some aspects, forming the conductive polymer can include tuning the conductivity of the conductive polymer based on a conductivity of the conductive layer such that a total conductivity of the reticle stage cleaning apparatus is tuned to a desired value. In some aspects, a stiffness of the conductive polymer can be lower than a stiffness of the conductive layer.

In some aspects, forming the conductive polymer can include tuning a mechanical property (e.g., stiffness, Young's modulus, elasticity, elastic modulus, adhesiveness, density, glass transition temperature, etc.) of the conductive polymer to a desired value. In some aspects, tuning the mechanical property can include using polymerization. In some aspects, tuning the mechanical property can include including an additive in the conductive polymer. In some aspects, tuning the mechanical property can include including a filler in the conductive polymer.

In some aspects, the method can further include contacting the reticle stage cleaning apparatus with a plurality of burls of an electrostatic clamp of the reticle stage. In some aspects, the method can further include generating an electrostatic field between the reticle stage cleaning apparatus and the electrostatic clamp. In some aspects, the method can further include removing particles disposed on the electrostatic clamp. In some aspects, the method can further include repeating the contacting, the generating, and the removing steps to further remove particles from the electrostatic clamp to the reticle stage cleaning apparatus.

Implementations of any of the techniques described above may include an EUV light source, a DUV light source, a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic illustration of a lithographic apparatus, according to an exemplary aspect.

FIG. 2 is a schematic perspective illustration of a reticle stage and a reticle, according to an exemplary aspect.

FIG. 3 is a schematic cross-sectional illustration of the reticle stage and the reticle shown in FIG. 2.

FIG. 4 is a schematic perspective illustration of a RTC apparatus, according to an exemplary aspect.

FIG. 5 is a schematic cross-sectional illustration of the RTC apparatus shown in FIG. 4.

FIGS. 6A-6F are schematic two-dimensional chemical structure depictions of different conductive polymers of the RTC apparatus shown in FIGS. 4 and 5.

FIGS. 7A-7C illustrate a process cycle to remove particles from the reticle stage to the RTC apparatus, according to an exemplary aspect.

FIG. 8 is a schematic perspective illustration of a RTC apparatus with a conductive layer having a plurality of layers, according to an exemplary aspect.

FIG. 9 is a schematic cross-sectional illustration of the RTC apparatus shown in FIG. 8.

FIG. 10 is a schematic perspective illustration of a RTC apparatus with a second conductive layer, according to an exemplary aspect.

FIG. 11 is a schematic cross-sectional illustration of the RTC apparatus shown in FIG. 10.

FIG. 12 is a schematic perspective illustration of a RTC apparatus with two conductive layers and no substrate, according to an exemplary aspect.

FIG. 13 is a schematic cross-sectional illustration of the RTC apparatus shown in FIG. 12.

FIG. 14 illustrates a manufacturing flow diagram for manufacturing a RTC apparatus, according to an exemplary aspect.

FIG. 15 illustrates a cleaning flow diagram for removing particles from a reticle stage to a RTC apparatus, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to effect such feature, structure, or characteristic in connection with other aspects whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Aspects of the disclosure may be implemented in hardware, firmware, software, or any combination thereof. Aspects of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such aspects in more detail, however, it is instructive to present an example environment in which aspects of the present disclosure may be implemented.

### Exemplary Lithographic System

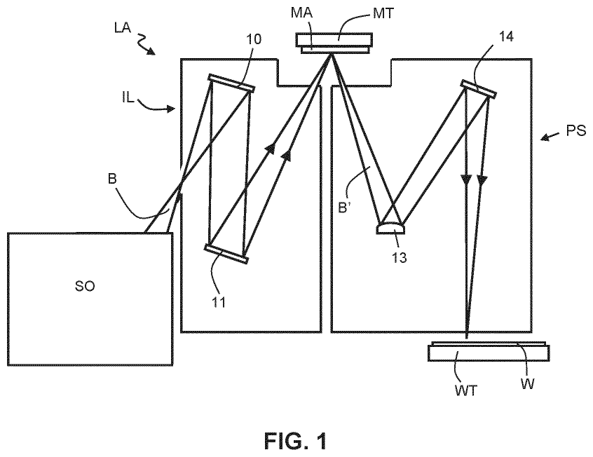

FIG. 1 shows a lithographic system comprising a radiation source SO and a lithographic apparatus LA. The radiation source SO is configured to generate an EUV and/or a DUV radiation beam B and to supply the EUV and/or DUV radiation beam B to the lithographic apparatus LA. The lithographic apparatus LA comprises an illumination system IL, a support structure MT (e.g., a mask table, a reticle table, a reticle stage) configured to support a patterning device MA (e.g., a mask, a reticle), a projection system PS, and a substrate table WT configured to support a substrate W.

The illumination system IL is configured to condition the EUV and/or DUV radiation beam B before the EUV and/or DUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV and/or DUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV and/or DUV radiation beam B interacts with the patterning device MA. This interaction may be reflective (as shown), which may be preferred for EUV radiation. This interaction may be transmissive, which may be preferred for DUV radiation. As a result of this interaction, a patterned EUV and/or DUV radiation beam B′ is generated. The projection system PS is configured to project the patterned EUV and/or DUV radiation beam B′ onto the substrate W. For that purpose, the projection system PS may comprise a plurality of mirrors 13, 14 which are configured to project the patterned EUV and/or DUV radiation beam B′ onto the substrate W held by the substrate table WT. The projection system PS may apply a reduction factor to the patterned EUV and/or DUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV and/or DUV radiation beam B′, with a pattern previously formed on the substrate W.

### Exemplary Reticle Stage Apparatus and Reticle Apparatus

As discussed above, a reticle stage (e.g., support structure MT) used in a lithographic apparatus (e.g., lithographic apparatus LA) to hold a patterning device (e.g., patterning device MA) can become contaminated over time (e.g., accumulate particles). The contamination can be transferred from the reticle stage to the patterning device, for example, by an electrostatic clamp that holds the patterning device during patterning.

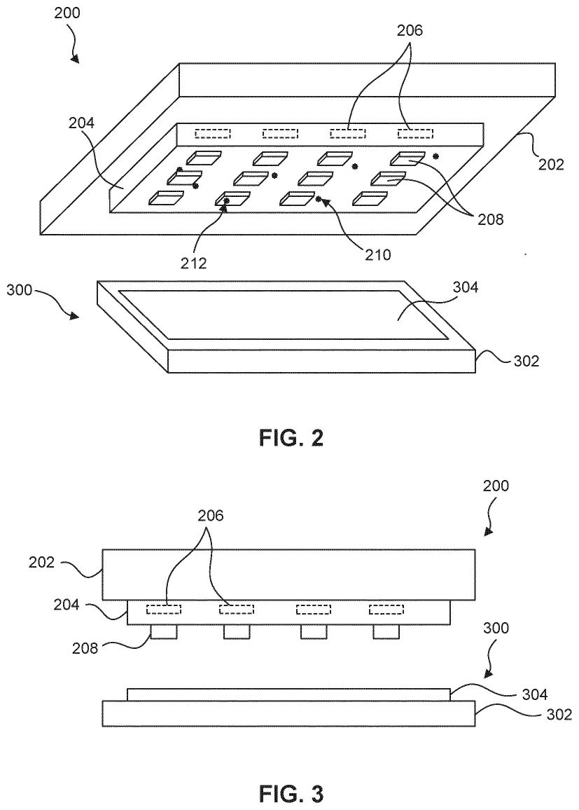

FIGS. 2 and 3 illustrate reticle stage 200 and reticle 300, according to various exemplary aspects. FIG. 2 is a schematic illustration of reticle stage 200 and reticle 300, according to an exemplary aspect. FIG. 3 is a schematic cross-sectional illustration of reticle stage 200 and reticle 300 shown in FIG. 2.

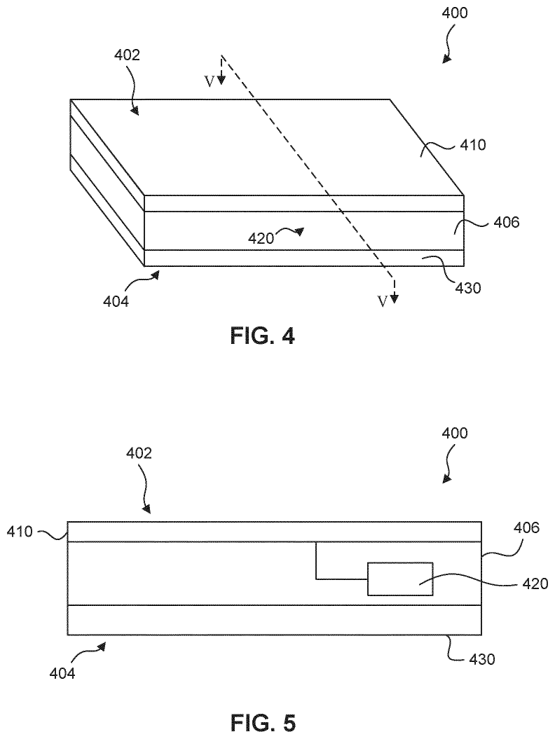

FIGS. 2 and 3 illustrate reticle stage 200, according to various exemplary aspects. Reticle stage 200 can be configured to support a patterning device (e.g., reticle 300). Reticle stage 200 can be further configured to support a cleaning apparatus (e.g., RTC apparatuses 400, 400′, 400″, 400″ shown in FIGS. 4-13). Although reticle stage 200 is shown in FIGS. 2 and 3 as a stand-alone apparatus and/or system, the aspects of this disclosure can be used with other apparatuses and/or systems, such as, but not limited to, lithographic apparatus LA, support structure MT, patterning device MA, reticle 300, and/or RTC apparatuses 400, 400′, 400″, 400″.

As shown in FIGS. 2 and 3, reticle stage 200 can include clamp chuck 202 and electrostatic clamp 204. Clamp chuck 202 can be configured to support electrostatic clamp 204 (e.g., by negative pressure). Electrostatic clamp 204 can be configured to support a patterning device (e.g., reticle 300) and/or a cleaning apparatus (e.g., RTC apparatuses 400, 400′, 400″, 400″) electrostatically. For example, a voltage can be applied to electrostatic clamp 204 to generate an electrostatic field between an object (e.g., reticle 300, RTC apparatuses 400, 400′, 400″, 400″) and electrostatic clamp 204 to hold the object.

As shown in FIGS. 2 and 3, electrostatic clamp 204 can include clamp electrodes 206 (e.g., embedded) and burls 208 (e.g., exterior projections or bumps). In some aspects, clamp electrodes 206 can be embedded in electrostatic clamp 204 and aligned (e.g., vertically) with burls 208. Clamp electrodes 206 can be configured to generate an electrostatic field between burls 208 and/or an object (e.g., reticle 300, RTC apparatuses 400, 400′, 400″, 400″). Burls 208 can be configured to physically contact an object (e.g., reticle 300, RTC apparatuses 400, 400′, 400″, 400″) in order to clamp (e.g., electrostatically) and hold the object.

In some aspects, as shown in FIG. 2, electrostatic clamp 204 can include various particles or contaminants on an exterior surface (e.g., contacting surface). For example, first particle 210 can be disposed between burls 208 and second particle 212 can be disposed on burls 208. Contaminants (e.g., first particle 210, second particle 212) can accumulate on electrostatic clamp 204 and cause patterning errors and/or defects. For example, contaminants (e.g., first particle 210, second particle 212) can be transferred to an object (e.g., reticle 300, RTC apparatuses 400, 400′, 400″, 400″) during electrostatic clamping of the object.

In some aspects, electrostatic clamp 204 can be configured to provide a voltage on an object (e.g., reticle 300, RTC apparatuses 400, 400′, 400″, 400″) relative to reticle stage 200 (e.g., burls 208 of electrostatic clamp 204). For example, clamp electrodes 206 can provide a voltage difference ΔV (e.g., from an applied negative voltage (−V) or positive voltage (+V)) between reticle stage 200 and the object such that an electrostatic field is generated between reticle stage 200 and the object. The generated electrostatic field creates an electrostatic force (e.g., Lorentz force) and/or a Van der Waals force on contaminants (e.g., first particle 210, second particle 212, etc.) and causes the contaminants to move from reticle stage 200 (e.g., electrostatic clamp 204) to the object.

FIGS. 2 and 3 illustrate reticle 300, according to various exemplary aspects. Reticle 300 can be configured to generate a patterned radiation beam (e.g., patterned EUV and/or DUV radiation beam B′). Although reticle 300 is shown in FIGS. 2 and 3 as a stand-alone apparatus and/or system, the aspects of this disclosure can be used with other apparatuses and/or systems, such as, but not limited to, lithographic apparatus LA, support structure MT, reticle stage 200, and/or patterning device MA.

As shown in FIGS. 2 and 3, reticle 300 can include patterning device 302 (e.g., patterning device MA) and backside layer 304. Backside layer 304 can be configured to contact burls 208 of electrostatic clamp 204 so that reticle stage 200 can hold (e.g., electrostatically) reticle 300 without damaging patterning device 302. Backside layer 304 can be disposed on a backside of patterning device 302. In some aspects, backside layer 304 can include a polymer or a combination of polymers. For example, backside layer 304 can include polyimide, Viton®, polytetrafluoroethylene (PTFE), Teflon, fluoropolymers, and/or any other material with a stiffness lower than that of patterning device 302. Contaminants (e.g., first particle 210, second particle 212) on electrostatic clamp 204 and/or reticle 300 can cause damage to electrostatic clamp 204, damage to reticle 300, and/or patterning errors (e.g., overlay misalignment or voids).

### Exemplary Reticle Table Cleaning (RTC) Apparatus

As discussed above, contaminants (e.g., first particle 210, second particle 212, etc.) can accumulate on a patterning device (e.g., reticle 300) and/or a patterning device support (e.g., reticle stage 200) and cause patterning errors and/or defects. A contaminated reticle stage (e.g., reticle stage 200) can be manually cleaned, but manual cleaning can leave a residue of fine particles, producing new contaminants. Further, manual cleaning requires the lithographic apparatus (e.g., lithographic apparatus LA) be vented to atmospheric pressure and partially disassembled, reducing overall yield.

Current RTC devices use an insulating top coating that can accumulate charge over multiple cycles (e.g., trapping of charge carriers in insulating coating). Under vacuum, RTC devices can eventually stick to the reticle stage due to parasitic charge between opposing insulating contact surfaces. Parasitic charge requires that the lithographic apparatus be vented to atmospheric pressure and partially dissembled in order to manually separate the RTC device from the reticle stage. One way to dissipate charge between the reticle stage (e.g., the electrostatic clamp) and an RTC device is to use a separate conductive device disposed between each load of the RTC device. However, this process slows scanning ability and overall efficiency of the lithographic apparatus since two devices are needed.

Aspects of RTC apparatuses, systems, and methods as discussed below may dissipate charge on the reticle stage, remove particles from the reticle stage, and improve efficiency, scanning ability, and overall yield in the lithographic apparatus.

FIGS. 4 and 5 illustrate RTC apparatus 400, according to various exemplary aspects. FIG. 4 is a schematic perspective illustration of RTC apparatus 400, according to an exemplary aspect. FIG. 5 is a schematic cross-sectional illustration of RTC apparatus 400 shown in FIG. 4 (along the plane indicated by V---V in FIG. 4). RTC apparatus 400 can be configured to clean reticle stage 200 in a lithographic apparatus (e.g., lithographic apparatus LA). RTC apparatus 400 can be further configured to dissipate charge accumulated on reticle stage 200 (e.g., accumulated charge on electrostatic clamp 204). RTC apparatus 400 can be further configured to remove contaminants (e.g., first particle 210, second particle 212, etc.) on reticle stage 200 (e.g., electrostatic clamp 204) via an electrostatic field generated between RTC apparatus 400 and reticle stage 200. Although RTC apparatus 400 is shown in FIGS. 4 and 5 as a stand-alone apparatus and/or system, the aspects of this disclosure can be used with other apparatuses and/or systems, such as, but not limited to, lithographic apparatus LA, support structure MT, reticle stage 200, patterning device MA, and/or reticle 300. In some aspects, RTC apparatus 400 can be part of a lithographic apparatus, for example, lithographic apparatus LA. In some aspects, RTC apparatus 400 can be part of a metrology apparatus.

As shown in FIGS. 4 and 5, RTC apparatus 400 can include frontside 402, backside 404, substrate 406, first frontside layer 410, voltage source 420, and/or positioner 430. RTC apparatus 400 has frontside 402 and backside 404 opposite frontside 402. Frontside 402 is configured to contact reticle stage 200. For example, frontside 402 can contact burls 208 of electrostatic clamp 204. In some aspects, substrate 406 can be disposed between first frontside layer 410 and positioner 430. In some aspects, substrate 406 can be an insulator. For example, substrate 406 can be quartz, silicon oxide, silicon, a glass, a ceramic, a semiconductor, and/or some combination thereof.

First frontside layer 410 can be configured to contact reticle stage 200 (e.g., burls 208 of electrostatic clamp 204) to dissipate charge accumulated on reticle stage 200. First frontside layer 410 can be further configured to contact reticle stage 200 (e.g., burls 208 of electrostatic clamp 204) to remove contaminants (e.g., first particle 210, second particle 212, etc.). First frontside layer 410 can be further configured to increase a conductivity of RTC apparatus 400 and thereby decrease charge accumulation on reticle stage 200 (e.g., drawing charge away from reticle stage 200). First frontside layer 410 can be further configured to increase an adhesion of RTC apparatus 400 contacting reticle stage 200. First frontside layer 410 can be further configured to decrease a stiffness of RTC apparatus 400 contacting reticle stage 200. First frontside layer 410 can be disposed on a frontside of substrate 406 (e.g., frontside 402).

In some aspects, first frontside layer 410 can be conductive. For example, first frontside layer 410 can have a conductivity of at least about 1 S/cm. In some aspects, first frontside layer 410 can have a conductivity of at least about 1 S/cm to decrease charge accumulation on reticle stage 200 and/or RTC apparatus 400. For example, the conductivity can be about 2 S/cm. In some aspects, first frontside layer 410 can have a conductivity of at least about 10 S/cm. For example, the conductivity can be about 20 S/cm. In some aspects, first frontside layer 410 can have a conductivity of at least about 100 S/cm. For example, the conductivity can be about 200 S/cm. In some aspects, first frontside layer 410 can have a conductivity of at least about 500 S/cm. For example, the conductivity can be about 600 S/cm. In some aspects, first frontside layer 410 can have a conductivity of at least about 1,000 S/cm. For example, the conductivity can be about 2,000 S/cm. In some aspects, first frontside layer 410 can have a conductivity of no greater than about 600 S/cm. In some aspects, first frontside layer 410 can have a conductivity of no greater than about 1,000 S/cm. In some aspects, first frontside layer 410 can have a conductivity of no greater than about 10,000 S/cm.

In some aspects, first frontside layer 410 can have a conductivity in a range between about 1 S/cm to about 600 S/cm to decrease charge accumulation on reticle stage 200 and/or RTC apparatus 400. In some aspects, first frontside layer 410 can have a conductivity in a range between about 10 S/cm to about 600 S/cm. In some aspects, first frontside layer 410 can have a conductivity in a range between about 100 S/cm to about 600 S/cm. In some aspects, first frontside layer 410 can have a conductivity in a range between about 100 S/cm to about 1,000 S/cm. In some aspects, first frontside layer 410 can have a conductivity in a range between about 100 S/cm to about 10,000 S/cm. In some aspects, first frontside layer 410 can have a conductivity that is variable (e.g., adjustable). For example, the conductivity can be tuned to a desired value, for example, about 10 S/cm. In some aspects, first frontside layer 410 can include a conductive polymer.

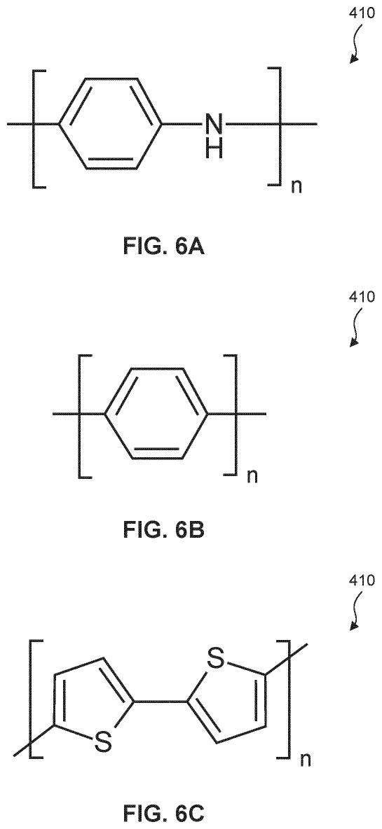

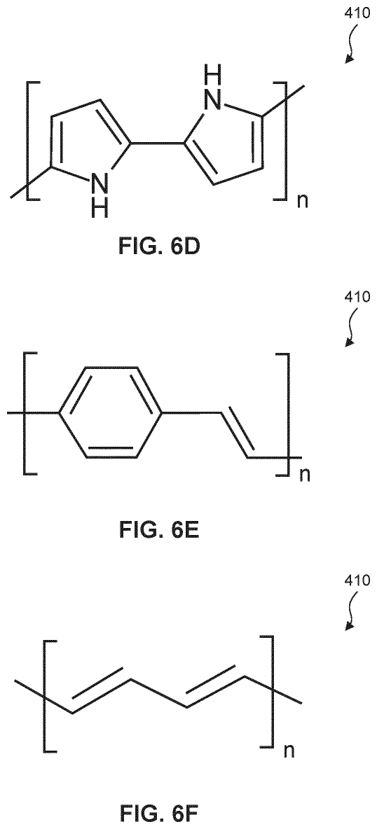

FIGS. 6A-6F are schematic two-dimensional chemical structure depictions of different conductive polymers of first frontside layer 410 of RTC apparatus 400 shown in FIGS. 4 and 5. FIGS. 6A-6F illustrate a repeating unit of polyaniline, poly-p-phenylene, polythiophene, polypyrrole, poly-p-phenylene vinylene, and trans-polyacetylene, respectively, that can be utilized to form first frontside layer 410. In some aspects, a conductivity of a conductive polymer of first frontside layer 410 can be in a range (e.g., variable) and can depend upon a chemical formation process used (e.g., polymerization, spin coating, slit coating, dip coating, spray coating, electrospinning, deposition, gravure coating, etc.), an additive added, and/or a filler added, for example, as shown below in Table I.

TABLE I
Conductivity Range of Conductive Polymers

| Compound | Repeating Unit | Conductivity (S/cm) |
|---|---|---|
| Polyaniline | 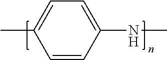 | ~2 × 10² |
| Poly-p-phenylene | 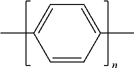 | 10² − 10³ |
| Polythiophene | 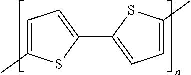 | ~10³ |
| Polypyrrole | 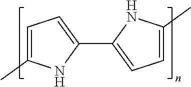 | 10² − 7.5 × 10³ |
| Poly-p-phenylene vinylene | 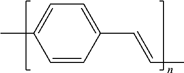 | ~2 × 10⁴ |
| trans-Polyacetylene | 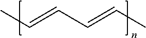 | 10³ − 10⁵ |

In some aspects, for example, as shown in FIGS. 6A-6F, first frontside layer 410 can include polyaniline, poly-p-phenylene, polythiophene, polypyrrole, poly-p-phenylene vinylene, trans-polyacetylene, or a combination thereof. In some aspects, a combination of polyaniline, poly-p-phenylene, polythiophene, polypyrrole, poly-p-phenylene vinylene, and/or trans-polyacetylene can include polymer blends, copolymers, and/or grafted polymers. In some aspects, first frontside layer 410 can include polyaniline. For example, as shown in FIG. 6A, first frontside layer 410 can be polyaniline and, for example, have a conductivity of about 10 S/cm. In some aspects, first frontside layer 410 can include poly-p-phenylene. For example, as shown in FIG. 6B, first frontside layer 410 can be poly-p-phenylene and, for example, have a conductivity of about 200 S/cm. In some aspects, first frontside layer 410 can include polythiophene. For example, as shown in FIG. 6C, first frontside layer 410 can be polythiophene and, for example, have a conductivity of about 500 S/cm. In some aspects, first frontside layer 410 can include polypyrrole. For example, as shown in FIG. 6D, first frontside layer 410 can be polypyrrole and, for example, have a conductivity of about 600 S/cm. In some aspects, first frontside layer 410 can include poly-p-phenylene vinylene. For example, as shown in FIG. 6E, first frontside layer 410 can be poly-p-phenylene vinylene and, for example, have a conductivity of about 1,000 S/cm. In some aspects, first frontside layer 410 can include trans-polyacetylene. For example, as shown in FIG. 6F, first frontside layer 410 can be trans-polyacetylene and, for example, have a conductivity of about 2,000 S/cm. In some aspects, first frontside layer 410 can include one or more conductive polymers. For example, first frontside layer 410 can include a combination of polyaniline and poly-p-phenylene, for example, alternating layers in a polymer stack.

In some aspects, first frontside layer 410 can include an additive configured to modify a conductivity and/or a mechanical property (e.g., stiffness, Young's modulus, elasticity, elastic modulus, adhesiveness, density, glass transition temperature, etc.) of first frontside layer 410. For example, the additive can include carbon, graphite, carbon black, carbon nanotubes, carbon fullerenes, metal particles, plasticizers, flame retardants, heat stabilizers, impact modifiers, antioxidants, colorants, lubricants, light stabilizers, quenchers, acid scavengers, pigments, antistatic agents, nucleating agents, tribological, slip compounds, or a combination thereof. In some aspects, first frontside layer 410 can include polyaniline, poly-p-phenylene, polythiophene, polypyrrole, poly-p-phenylene vinylene, trans-polyacetylene, or a combination thereof with an additive. For example, first frontside layer 410 can include poly-p-phenylene with plasticizers (e.g., camphor, n-ethyl-p-toluenesulfonamide, n-butylbenzensulfonamide, 2-nitrobiphenyl, etc.).

In some aspects, first frontside layer 410 can include a filler configured to modify a conductivity and/or a mechanical property (e.g., stiffness, Young's modulus, elasticity, elastic modulus, adhesiveness, density, glass transition temperature, etc.) of first frontside layer 410. For example, the filler can include carbon, graphite, carbon black, carbon nanotubes, carbon fullerenes, metal particles, wood, fiber, glass fiber, carbon fiber, minerals, calcium carbonate, clay, kaolin, titanium dioxide, talc, wollastonite, glass, mica, aluminum trihydrate, nanofillers, or a combination thereof. In some aspects, the filler can include an organic material, an inorganic material, a polymeric material, a metallic material, a ceramic material, or a combination thereof. In some aspects, first frontside layer 410 can include polyaniline, poly-p-phenylene, polythiophene, polypyrrole, poly-p-phenylene vinylene, trans-polyacetylene, or a combination thereof with a filler. For example, first frontside layer 410 can include polypyrrole with kaolin.

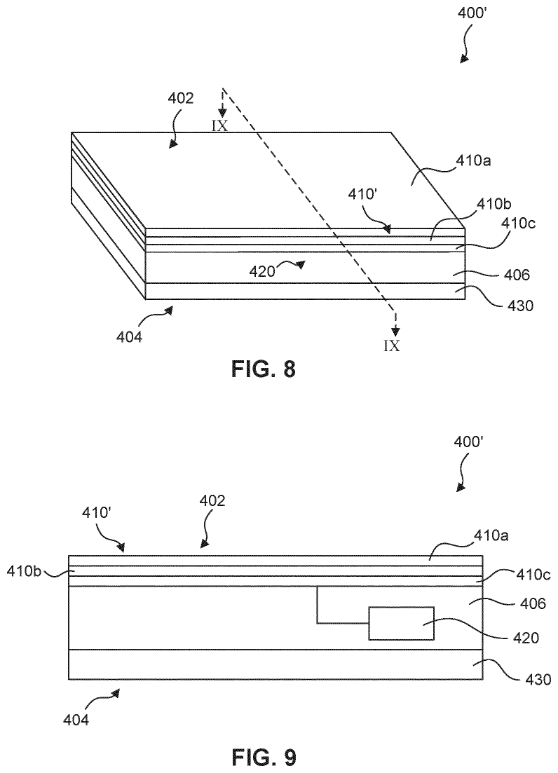

In some aspects, first frontside layer 410 can include a single layer. For example, as shown in FIGS. 4 and 5, first frontside layer 410 can be a single layer (e.g., polyaniline). In some aspects, first frontside layer 410 can include a plurality of layers. For example, as shown in FIGS. 8 and 9, first frontside layer 410′ can be a plurality of layers 410a, 410b, 410c (e.g., polyaniline, polythiophene, and polypyrrole, respectively.)

In some aspects, first frontside layer 410 can have a stiffness that is lower than a stiffness of substrate 406. For example, first frontside layer 410 can have a stiffness of about 50 N/m and substrate 406 can have a stiffness of about 1800 N/m. In some aspects, first frontside layer 410 can be substantially planar. For example, as shown in FIGS. 4 and 5, first frontside layer 410 can be planar (e.g., uniform thickness). In some aspects, first frontside layer 410 can have a thickness no greater than about 8 microns in order to generate an electrostatic field between first frontside layer 410 and reticle stage 200.

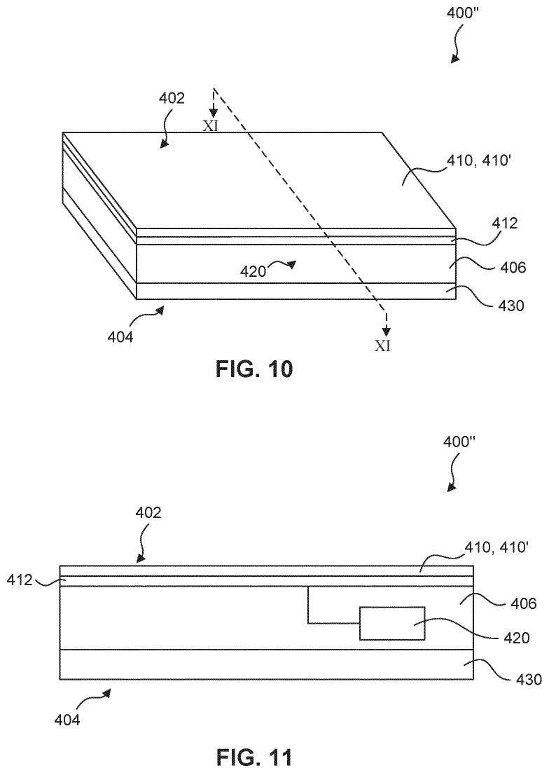

In some aspects, RTC apparatus 400 can further include second frontside layer 412 disposed between first frontside layer 410 and substrate 406. For example, as shown in FIGS. 10 and 11, second frontside layer 412 can be conductive (e.g., a conductive metal, a conductive nitride, a conductive polymer, etc.) and disposed below first frontside layer 410, 410′. In some aspects, second frontside layer 412 can have a conductivity in a range of about 50 S/cm to about 850 S/cm. In some aspects, second frontside layer 412 can include chromium nitride, titanium nitride, carbon nitride, or any other rigid conductive material. In some aspects, first frontside layer 410 can have a stiffness that is lower than a stiffness of second frontside layer 412.

In some aspects, first frontside layer 410 can have a conductivity that is variable (e.g., adjustable) and that is configured to compensate for a conductivity of second frontside layer 412, such that a total conductivity of RTC apparatus 400 can be tuned to a desired value. For example, second frontside layer 412 can have a conductivity (G₂) of about 600 S/cm and a conductivity (G₁) of first frontside layer 410 can be tuned to about 400 S/cm, such that a total conductivity is tuned to a desired value, for example, about 240 S/cm, e.g.,

$${G}_{Total}^{- 1} = ( \frac{1}{{G}_{1}} ) + ( \frac{1}{{G}_{2}} ) .$$

example, second frontside layer 412 can have a conductivity (G₂) of about 600 S/cm and a conductivity (G₁) of first frontside layer 410 can be tuned to about 1,800 S/cm, such that a total conductivity is tuned to a desired value, for example, about 450 S/cm.

Voltage source 420 can be configured to provide a voltage on first frontside layer 410 relative to reticle stage 200 (e.g., burls 208 of electrostatic clamp 204). For example, voltage source 420 can be electrically coupled to first frontside layer 410 to provide a voltage difference ΔV (e.g., from applied negative voltage (−V) or positive voltage (+V)) between reticle stage 200 and RTC apparatus 400 such that an electrostatic field is generated between reticle stage 200 and RTC apparatus 400. The generated electrostatic field creates an electrostatic force (e.g., Lorentz force) and/or a Van der Waals force on contaminants (e.g., first particle 210, second particle 212) and causes the contaminants to move from reticle stage 200 (e.g., electrostatic clamp 204) to RTC apparatus 400 (e.g., first frontside layer 410).

In some aspects, voltage source 420 can be internal to RTC apparatus 400. For example, as shown in FIG. 5, voltage source 420 can be embedded or disposed within substrate 406. In some aspects, voltage source 420 can be external to RTC apparatus 400. In some aspects, voltage source 420 can be a battery powered voltage source configured to provide a high voltage on frontside 402 of RTC apparatus 400. In some aspects, voltage source 420 can provide a voltage of about 1 kV to about 5 kV.

In some aspects, RTC apparatus 400 can omit voltage source 420 and first frontside layer 410 can act as a passive conductor (e.g., first frontside layer 410 can be grounded or maintained at 0 V). For example, clamp electrodes 206 of electrostatic clamp 204 can provide a voltage on burls 208 relative to first frontside layer 410 to generate an electrostatic field between electrostatic clamp 204 and first frontside layer 410.

Positioner 430 can be configured to translate first frontside layer 410 relative to reticle stage 200. For example, positioner 430 can translate first frontside layer 410 along a vertical direction (e.g., Z-axis) towards burls 208 of electrostatic clamp 204. In some aspects, positioner 430 can be a six-axis translation stage (e.g., X, Y, Z, yaw, pitch, roll) for six degrees of freedom. For example, positioner 430 can be configured to contact RTC apparatus 400 (e.g., first frontside layer 410) with reticle stage 200 in a first surface area, retract RTC apparatus 400 from the first area, translate RTC apparatus 400 to a second surface area of reticle stage 200, and contact RTC apparatus (e.g., first frontside layer 410) with reticle stage 200 in the second surface area. In some aspects, positioner 430 can include one or more linear motors (e.g., servomotors). In some aspects, positioner 430 can be positioned at backside 404 of RTC apparatus 400. For example, as shown in FIGS. 4 and 5, substrate 406 can be disposed atop positioner 430. In some aspects, positioner 430 can be an exchange device for loading one or more reticles (e.g., RTC apparatus 400) onto electrostatic clamp 204.

### Exemplary Process Cycle

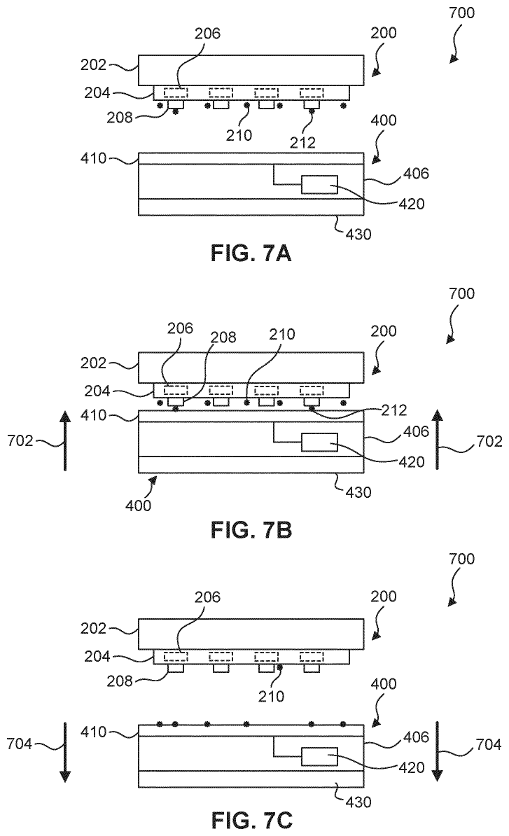

FIGS. 7A-7C illustrate process cycle 700 to remove contaminants (e.g., first particle 210, second particle 212, etc.) from reticle stage 200 to RTC apparatus 400, according to various exemplary aspects. FIG. 7A is a schematic cross-sectional illustration of reticle stage 200 and RTC apparatus 400 in an initial step. FIG. 7B is a schematic cross-sectional illustration of reticle stage 200 and RTC apparatus 400 in a contact step. FIG. 7C is a schematic cross-sectional illustration of reticle stage 200 and RTC apparatus 400 in a retract step.

As shown in FIG. 7A, RTC apparatus 400 can approach burls 208 of electrostatic clamp 204 of reticle stage 200 such that burls 208 oppose first frontside layer 410 (e.g., conductive) in a substantially perpendicular direction in an initial step. For example, positioner 430 can align first frontside layer 410 with burls 208 of electrostatic clamp 204. Contaminants (e.g., first particle 210, second particle 212, etc.) are disposed on an exterior surface of electrostatic clamp 204.

As shown in FIG. 7B, RTC apparatus 400 can translate vertically (e.g., +Z-axis) towards reticle stage 200 along contact direction 702 and physically contact burls 208 of electrostatic clamp 204 in a contact step. During the contact step, a voltage difference ΔV can be applied between RTC apparatus 400 and reticle stage 200 (e.g., by applying voltage to clamp electrodes 206 and/or first frontside layer 410) to generate an electrostatic field between RTC apparatus 400 and reticle stage 200. The generated electrostatic field creates an electrostatic force (e.g., Lorentz force) and/or a Van der Waals force on contaminants (e.g., first particle 210, second particle 212, etc.) and causes the contaminants to move from reticle stage 200 to RTC apparatus 400. Contaminants (e.g., first particle 210, second particle 212, etc.) contact first frontside layer 410 and remain on frontside 402. Further, any charge accumulated on electrostatic clamp 204 can be dissipated when first frontside layer 410 (e.g., conductive) contacts electrostatic clamp 204.

As shown in FIG. 7C, RTC apparatus 400 can translate vertically (e.g., −Z-axis) away from reticle stage 200 along retract direction 704 and retract from burls 208 of electrostatic clamp 204 in a retract step. During the retract step, frontside 402 of RTC apparatus 400 can retain most if not all of contaminants (e.g., first particle 210, second particle 212, etc.) from electrostatic clamp 204 on first frontside layer 410.

In some aspects, the contact step shown in FIG. 7B and the retract step shown in FIG. 7C can be repeated (e.g., multiple cycles) to further remove contaminants (e.g., first particle 210, second particle 212, etc.) from electrostatic clamp 204 to RTC apparatus 400. In some aspects, process cycle 700 can include contacting reticle stage 200 with RTC apparatus 400 in a first surface area, retracting RTC apparatus 400, translating RTC apparatus 400 (e.g., via positioner 430), and contacting reticle stage 200 with RTC apparatus 400 in a second surface area different from the first surface area.

### Exemplary Alternative RTC Apparatuses

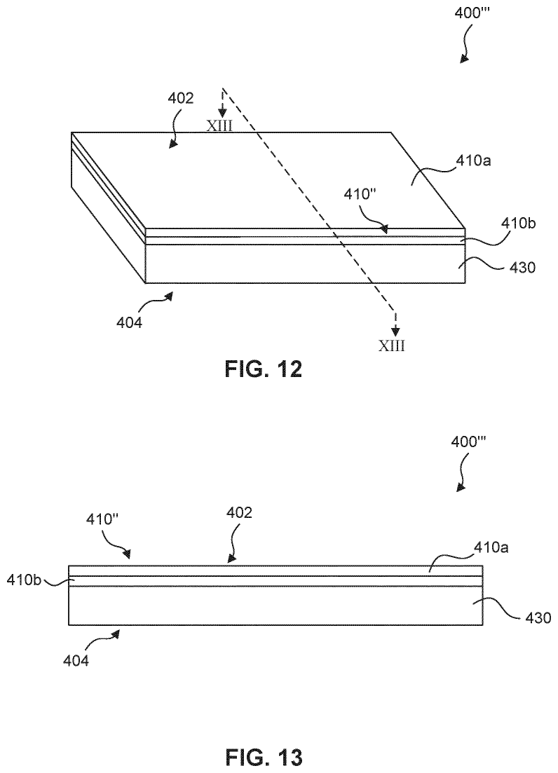

FIGS. 8-13 illustrate RTC apparatuses 400′, 400″, 400″ according to various exemplary aspects. FIG. 8 is a schematic perspective illustration of RTC apparatus 400′, according to an exemplary aspect. FIG. 9 is a schematic cross-sectional illustration of RTC apparatus 400′ shown in FIG. 8 (along the plane indicated by IX---IX in FIG. 8). FIG. 10 is a schematic perspective illustration of RTC apparatus 400″, according to an exemplary aspect. FIG. 11 is a schematic cross-sectional illustration of RTC apparatus 400″ shown in FIG. 10 (along the plane indicated by XI---XI in FIG. 10). FIG. 12 is a schematic perspective illustration of RTC apparatus 400″, according to an exemplary aspect. FIG. 13 is a schematic cross-sectional illustration of RTC apparatus 400″ shown in FIG. 12 (along the plane indicated by XI---XI in FIG. 12).

FIGS. 8 and 9 illustrate RTC apparatus 400′, according to certain aspects. The aspects of RTC apparatus 400 shown in FIGS. 4 and 5, for example, and the aspects of RTC apparatus 400′ shown in FIGS. 8 and 9 may be similar. Similar reference numbers are used to indicate features of the aspects of RTC apparatus 400 shown in FIGS. 4 and 5 and the similar features of the aspects of RTC apparatus 400′ shown in FIGS. 8 and 9. One difference between the aspects of RTC apparatus 400 shown in FIGS. 4 and 5 and the aspects of RTC apparatus 400′ shown in FIGS. 8 and 9 is that RTC apparatus 400′ includes first frontside layer 410′ with a plurality of layers 410a, 410b, 410c, rather than just first frontside layer 410 (e.g., single layer) shown in FIGS. 4 and 5. Although RTC apparatus 400′ is shown in FIGS. 8 and 9 as a stand-alone apparatus and/or system, the aspects of this disclosure can be used with other apparatuses and/or systems, such as, but not limited to, lithographic apparatus LA, support structure MT, reticle stage 200, patterning device MA, and/or reticle 300.

As shown in FIGS. 8 and 9, RTC apparatus 400′ can include first frontside layer 410′ with a plurality of layers 410a, 410b, 410c. In some aspects, first frontside layer 410′ can include two layers, for example, plurality of layers 410a, 410b. In some aspects, first frontside layer 410′ can include more than two layers, for example, plurality of layers 410a, 410b, 410c. In some aspects, first frontside layer 410′ can include alternating conductive polymer layers, for example, plurality of layers 410a, 410b (e.g., polyaniline and polypyrrole, respectively). In some aspects, first frontside layer 410′ can include an additive and/or a filler, for example, plurality of layers 410a, 410b, 410c (e.g., polypyrrole, calcium carbonate, and trans-polyacetylene, respectively).

FIGS. 10 and 11 illustrate RTC apparatus 400″, according to certain aspects. The aspects of RTC apparatus 400 shown in FIGS. 4 and 5, for example, and the aspects of RTC apparatus 400″ shown in FIGS. 10 and 11 may be similar. Similar reference numbers are used to indicate features of the aspects of RTC apparatus 400 shown in FIGS. 4 and 5 and the similar features of the aspects of RTC apparatus 400″ shown in FIGS. 10 and 11. One difference between the aspects of RTC apparatus 400 shown in FIGS. 4 and 5 and the aspects of RTC apparatus 400″ shown in FIGS. 10 and 11 is that RTC apparatus 400″ includes second frontside layer 412 disposed between substrate 406 and first frontside layer 410, rather than just first frontside layer 410 shown in FIGS. 4 and 5. Although RTC apparatus 400″ is shown in FIGS. 10 and 11 as a stand-alone apparatus and/or system, the aspects of this disclosure can be used with other apparatuses and/or systems, such as, but not limited to, lithographic apparatus LA, support structure MT, reticle stage 200, patterning device MA, and/or reticle 300.

As shown in FIGS. 10 and 11, RTC apparatus 400″ can include second frontside layer 412. Second frontside layer 412 can be configured to generate an electrostatic field between reticle stage 200 and RTC apparatus 400″. Second frontside layer 412 can be further configured to generate the electrostatic field to remove contaminants (e.g., first particle 210, second particle 212, etc.) on reticle stage 200 (e.g., electrostatic clamp 204). In some embodiments, as shown in FIG. 11, second frontside layer 412 can be electronically coupled to voltage source 420 in order to provide a voltage on second frontside layer 412.

In some aspects, second frontside layer 412 can be conductive (e.g., a conductive metal, a conductive nitride, a conductive polymer, etc.) and disposed below first frontside layer 410, 410′. In some aspects, second frontside layer 412 can have a conductivity in a range of about 50 S/cm to about 850 S/cm. For example, second frontside layer 412 can have a conductivity in a range of about 200 S/cm to about 700 S/cm. In some aspects, second frontside layer 412 can include chromium nitride, titanium nitride, carbon nitride, or any other rigid conductive material. For example, second frontside layer 412 can be chromium nitride. In some aspects, first frontside layer 410, 410′ can have a stiffness that is lower than a stiffness of second frontside layer 412. For example, first frontside layer 410, 410′ can have a stiffness of about 100 N/m and second frontisde layer 412 can have a stiffness of about 1500 N/m. In some aspects, second frontside layer 412 can be substantially planar. For example, as shown in FIGS. 10 and 11, second frontside layer 412 can be planar (e.g., uniform thickness). In some aspects, second frontside layer 412 can have a thickness no greater than about 8 microns in order to generate an electrostatic field between first frontside layer 410, 410′ and reticle stage 200.

FIGS. 12 and 13 illustrate RTC apparatus 400″, according to certain aspects. The aspects of RTC apparatus 400 shown in FIGS. 4 and 5, for example, and the aspects of RTC apparatus 400″ shown in FIGS. 12 and 13 may be similar. Similar reference numbers are used to indicate features of the aspects of RTC apparatus 400 shown in FIGS. 4 and 5 and the similar features of the aspects of RTC apparatus 400″ shown in FIGS. 12 and 13. One difference between the aspects of RTC apparatus 400 shown in FIGS. 4 and 5 and the aspects of RTC apparatus 400″ shown in FIGS. 12 and 13 is that RTC apparatus 400″ includes first frontside layer 410″ with first and second layers 410a, 410b and omits substrate 406, rather than first frontside layer 410 and substrate 406 shown in FIGS. 4 and 5. Although RTC apparatus 400″ is shown in FIGS. 12 and 13 as a stand-alone apparatus and/or system, the aspects of this disclosure can be used with other apparatuses and/or systems, such as, but not limited to, lithographic apparatus LA, support structure MT, reticle stage 200, patterning device MA, and/or reticle 300.

As shown in FIGS. 12 and 13, RTC apparatus 400′ can include first frontside layer 410″ with first and second layers 410a, 410b. In some aspects, first frontside layer 410″ can include conductive polymer layers, for example, first and second layers 410a, 410b can include polyaniline, poly-p-phenylene, polythiophene, polypyrrole, poly-p-phenylene vinylene, trans-polyacetylene, or a combination thereof, for example, polymer blends, copolymers, and/or grafted polymers. In some aspects, first frontside layer 410″ can include different conductive polymer layers, for example, first and second layers 410a, 410b (e.g., polyaniline and polypyrrole, respectively). In some aspects, first frontside layer 410″ can include an additive and/or a filler, for example, first and second layers 410a, 410b (e.g., polypyrrole and calcium carbonate, respectively). In some aspects, for example, as shown in FIGS. 12 and 13, first frontside layer 410″ can be formed directly on positioner 430 (e.g., substrate 406 can be omitted). In some aspects, first and second layers 410a, 410b can include conductive polymers (e.g., polyaniline, poly-p-phenylene, polythiophene, polypyrrole, poly-p-phenylene vinylene, trans-polyacetylene, or a combination thereof), for example, conductive polymers having an equivalent or higher conductivity than chromium nitride (CrN).

In some aspects, first layer 410a can be conductive and disposed above second layer 410b. In some aspects, first layer 410a can have a conductivity in a range of about 1 S/cm to about 600 S/cm. For example, first layer 410a can have a conductivity in a range of about 10 S/cm to about 300 S/cm. In some aspects, second layer 410b can be conductive and disposed below first layer 410a. In some aspects, second layer 410b can have a conductivity in a range of about 50 S/cm to about 850 S/cm. For example, second layer 410b can have a conductivity in a range of about 200 S/cm to about 700 S/cm. In some aspects, first and second layers 410a, 410b can have a total conductivity in a range of about 50 S/cm to about 850 S/cm. For example, first and second layers 410a, 410b can have a total conductivity in a range of about 200 S/cm to about 700 S/cm.

### Exemplary Manufacturing Flow Diagram

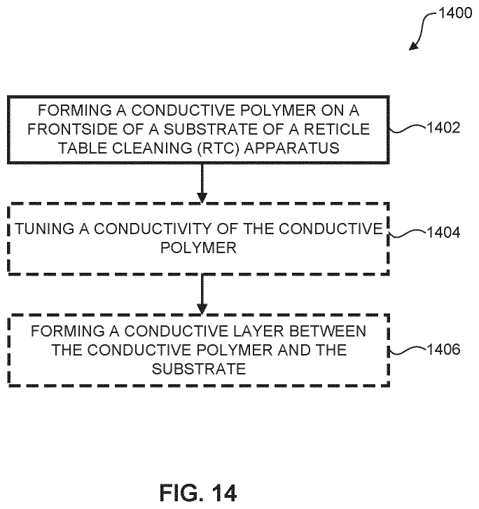

FIG. 14 illustrates manufacturing flow diagram 1400 for manufacturing RTC apparatuses 400, 400′, 400″, 400″, according to an exemplary aspect. It is to be appreciated that not all steps in FIG. 14 are needed to perform the disclosure provided herein. Further, some of the steps may be performed simultaneously, sequentially, and/or in a different order than shown in FIG. 14. Manufacturing flow diagram 1400 shall be described with reference to FIGS. 4, 5, 6A-6F, and 8-11. However, manufacturing flow diagram 1400 is not limited to those example aspects.

In step 1402, as shown in the example of FIGS. 4, 5, and 6A-6F, first frontside layer 410 can include a conductive polymer (e.g., polyaniline, poly-p-phenylene, polythiophene, polypyrrole, poly-p-phenylene vinylene, trans-polyacetylene) and be formed atop substrate 406. In some aspects, first frontside layer 410 can be formed by using polymerization. In some aspects, first frontside layer 410 can be formed by spin coating (e.g., coating substrate 406 with a conductive polymer and rotating for uniform thickness), slit coating (e.g., casting a conductive polymer through a slit onto substrate 406), dip coating (e.g., dipping substrate 406 into a conductive polymer and pressing excess with rollers), spray coating (e.g., spraying a conductive polymer directly on substrate 406), electrospinning (e.g., spinning a conductive polymer directly on substrate 406), deposition, gravure coating (e.g., printing a conductive polymer with a rotary printing press directly on substrate 406), or a combination thereof. In some aspects, for example, as shown in FIGS. 12 and 13, first frontside layer 410 can be formed directly on positioner 430 (e.g., substrate 406 can be omitted) and the above mentioned processes can be performed on positioner 430.

In some aspects, first frontside layer 410 can be formed by deposition. For example, first frontside layer 410 can be formed or deposited by any suitable method including chemical vapor deposition (CVD), plasma-enhanced CVD (PECVD), low pressure CVD (LPCVD), atomic layer deposition (ALD), pulsed laser deposition (PLD), electron beam physical vapor deposition (EBPVD), sputtering (e.g., RF, electronic, potential, chemical), ion-beam deposition, spin-on deposition, liquid source misted chemical deposition, and/or other suitable deposition methods. In some aspects, forming first frontside layer 410 can include forming a plurality of layers, for example, as shown in FIGS. 8 and 9, plurality of layers 410a, 410b, 410c.

In step 1404, optionally, as shown in the example of FIGS. 4, 5, and 6A-6F, a conductivity of first frontside layer 410 can be tuned to a desired value. In some aspects, step 1404 can take place during step 1402. In some aspects, tuning the conductivity of first frontside layer 410 can include polymerization. For example, a repeating unit of a conductive polymer (e.g., polyaniline, poly-p-phenylene, polythiophene, polypyrrole, poly-p-phenylene vinylene, trans-polyacetylene) can be polymerized to form first frontside layer 410 with a desired conductivity. In some aspects, the polymerization can be tuned by adjusting temperature, pressure, duration, rate, length of repeating unit, thickness, branching, copolymer, tacticity, light curing, steric hindrance, electronegativity, solvent type, solubility, charge distribution, molecular stability, or a combination thereof.

In some aspects, tuning the conductivity of first frontside layer 410 can include including an additive in first frontside layer 410. For example, the additive can include carbon, graphite, carbon black, carbon nanotubes, carbon fullerenes, metal particles, plasticizers, flame retardants, heat stabilizers, impact modifiers, antioxidants, colorants, lubricants, light stabilizers, quenchers, acid scavengers, pigments, antistatic agents, nucleating agents, tribological, slip compounds, or a combination thereof to increase or decrease the conductivity of first frontside layer 410.

In some aspects, tuning the conductivity of first frontside layer 410 can include including a filler in first frontside layer 410. For example, the filler can include carbon, graphite, carbon black, carbon nanotubes, carbon fullerenes, metal particles, wood, fiber, glass fiber, carbon fiber, minerals, calcium carbonate, clay, kaolin, titanium dioxide, talc, wollastonite, glass, mica, aluminum trihydrate, nanofillers, or a combination thereof to increase or decrease the conductivity of first frontside layer 410.

In step 1406, optionally, as shown in the example of FIGS. 10 and 11, second frontside layer 412 can be formed between substrate 406 and first frontside layer 410, 410′. In some aspects, first frontside layer 410, 410′ can be formed atop second frontside layer 412 subsequent to second frontside layer 412 being formed atop substrate 406. In some aspects, second frontside layer 412 can be formed by deposition. For example, second frontside layer 412 can be formed or deposited by any suitable method including CVD, PECVD, LPCVD, ALD, PLD, EBPVD, sputtering (e.g., RF, electronic, potential, chemical), ion-beam deposition, spin-on deposition, liquid source misted chemical deposition, and/or other suitable deposition methods. In some aspects, second frontside layer 412 can be conductive (e.g., a conductive metal, a conductive nitride, a conductive polymer, etc.) and disposed below first frontside layer 410, 410′. In some aspects, second frontside layer 412 can have a conductivity in a range of about 50 S/cm to about 850 S/cm. For example, second frontside layer 412 can have a conductivity in a range of about 200 S/cm to about 700 S/cm. In some aspects, second frontside layer 412 can include chromium nitride, titanium nitride, carbon nitride, or any other rigid conductive material. For example, second frontside layer 412 can be chromium nitride.

In some aspects, forming first frontside layer 410, 410′ can include tuning a conductivity of first frontside layer 410, 410′ based on a conductivity of second frontside layer 412, such that a total conductivity of RTC apparatus 400″ can be tuned to a desired value. For example, second frontside layer 412 can have a conductivity (G₂) of about 600 S/cm and a conductivity (G₁) of first frontside layer 410, 410′ can be tuned to about 400 S/cm, such that a total conductivity of RTC apparatus 400″ (e.g., in series, along a vertical direction) is tuned to a desired value, for example, about 240 S/cm,

$$e . g . , {G}_{Total}^{- 1} = ( \frac{1}{{G}_{1}} ) + ( \frac{1}{{G}_{2}} ) .$$

### Exemplary Cleaning Flow Diagram

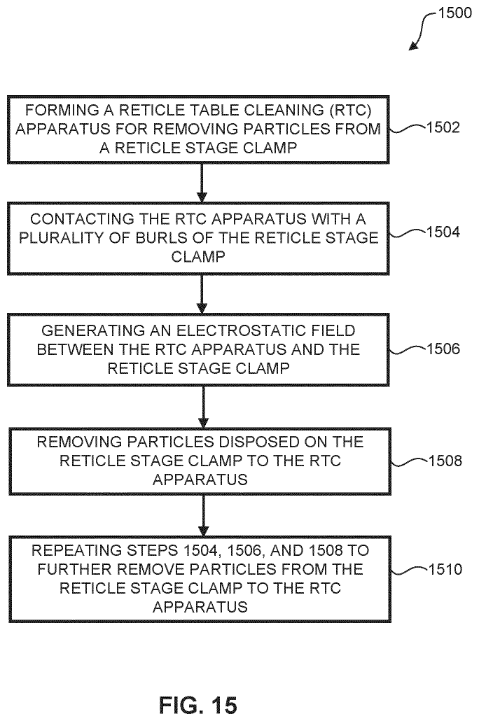

FIG. 15 illustrates cleaning flow diagram 1500 for removing contaminants (e.g., first particle 210, second particle 212, etc.) from reticle stage 200 to RTC apparatuses 400, 400′, 400″, 400″, according to an exemplary aspect. It is to be appreciated that not all steps in FIG. 15 are needed to perform the disclosure provided herein. Further, some of the steps may be performed simultaneously, sequentially, and/or in a different order than shown in FIG. 15. Cleaning flow diagram 1500 shall be described with reference to FIGS. 4-13. However, cleaning flow diagram 1500 is not limited to those example aspects.

In step 1502, as shown in the example of FIGS. 4-13, RTC apparatus 400, 400′, 400″, 400″ can be formed for removing contaminants (e.g., first particle 210, second particle 212, etc.) from reticle stage 200. In some aspects, as shown in FIG. 14, RTC apparatuses 400, 400′, 400″, 400′″ can be formed using manufacturing flow diagram 1400.

In step 1504, as shown in the example of FIG. 7B, RTC apparatus 400, 400′, 400″, 400″ can contact burls 208 of electrostatic clamp 204 of reticle stage 200. In some aspects, RTC reticles 400, 400′, 400″, 400″ can physically contact burls 208 of electrostatic clamp 204 of reticle stage 200 such that burls 208 oppose first frontside layer 410 (e.g., conductive) in a substantially perpendicular direction. For example, positioner 430 can align first frontside layer 410 with burls 208 of electrostatic clamp 204.

In step 1506, as shown in the example of FIG. 7B, one or more electrostatic fields can be generated between RTC apparatus 400, 400′, 400″, 400′″ and electrostatic clamp 204 of reticle stage 200. In some aspects, a voltage difference ΔV can be applied between RTC apparatus 400 and reticle stage 200 (e.g., by applying voltage to clamp electrodes 206, first frontside layer 410, and/or second frontside layer 412) to generate an electrostatic field between RTC apparatus 400 and reticle stage 200.

In step 1508, as shown in the example of FIG. 7C, contaminants (e.g., first particle 210, second particle 212, etc.) disposed on electrostatic clamp 204 can be removed from reticle stage 200 to RTC apparatus 400, 400′, 400″, 400″. In some aspects, the one or more generated electrostatic fields create an electrostatic force(s) (e.g., Lorentz force) and/or a Van der Waals force(s) on contaminants (e.g., first particle 210, second particle 212, etc.) and causes the contaminants to move from reticle stage 200 to RTC apparatus 400. Contaminants (e.g., first particle 210, second particle 212, etc.) contact first frontside layer 410 (e.g., conductive) and remain on frontside 402. Further, any charge accumulated on electrostatic clamp 204 can be dissipated when first frontside layer 410 (e.g., conductive) contacts electrostatic clamp 204.

In step 1510, as shown in the example of FIGS. 7A-7C, steps 1504, 1506, and 1508 can be repeated (e.g., multiple cycles) to further remove contaminants (e.g., first particle 210, second particle 212, etc.) from electrostatic clamp 204 to RTC apparatus 400, 400′, 400″, 400″.

Various embodiments of the present systems and methods are disclosed in the subsequent list of numbered clauses:
1. A cleaning apparatus for a clamp in a lithographic apparatus, the apparatus comprising:
   a substrate having a frontside and a backside opposite the frontside; and
   a conductive layer disposed on the frontside of the substrate and configured to contact the clamp to dissipate charge on the clamp and to remove particles on the clamp via an electrostatic field generated between the conductive layer and the clamp.
2. The apparatus of clause 1, wherein a conductivity of the conductive layer is at least about 1 S/cm.
3. The apparatus of clause 1, wherein a conductivity of the conductive layer is at least about 10 S/cm.
4. The apparatus of clause 1, wherein a conductivity of the conductive layer is at least about 100 S/cm.
5. The apparatus of clause 1, wherein a conductivity of the conductive layer is in a range between about 1 S/cm to about 600 S/cm.
6. The apparatus of clause 1, wherein a conductivity of the conductive layer is in a range between about 10 S/cm to about 600 S/cm.
7. The apparatus of clause 1, wherein a conductivity of the conductive layer is in a range between about 100 S/cm to about 600 S/cm.
8. The apparatus of clause 1, wherein a conductivity of the conductive layer is variable and configured to be tuned to a desired value.
9. The apparatus of clause 1, wherein the conductive layer comprises a conductive polymer.
10. The apparatus of clause 9, wherein the conductive polymer comprises polyaniline, poly-p-phenylene, polythiophene, polypyrrole, poly-p-phenylene vinylene, trans-polyacetylene, or a combination thereof.
11. The apparatus of clause 9, wherein the conductive polymer comprises an additive configured to modify a conductivity and/or a mechanical property of the conductive polymer.
12. The apparatus of clause 11, wherein the additive comprises carbon, graphite, carbon black, carbon nanotubes, carbon fullerenes, metal particles, plasticizers, flame retardants, heat stabilizers, impact modifiers, antioxidants, colorants, lubricants, light stabilizers, quenchers, acid scavengers, pigments, antistatic agents, nucleating agents, tribological, slip compounds, or a combination thereof.
13. The apparatus of clause 9, wherein the conductive polymer comprises a filler configured to modify a conductivity and/or a mechanical property of the conductive polymer.
14. The apparatus of clause 13, wherein the filler comprises an organic material, an inorganic material, a polymeric material, a metallic material, a ceramic material, or a combination thereof.
15. The apparatus of clause 9, wherein the conductive polymer comprises a single layer.
16. The apparatus of clause 9, wherein the conductive polymer comprises a plurality of layers.
17. The apparatus of clause 9, wherein the conductive polymer comprises a surface treatment and/or a surface modification.
18. The apparatus of clause 1, further comprising a second conductive layer disposed between the conductive layer and the substrate.
19. The apparatus of clause 18, wherein a stiffness of the conductive layer is lower than a stiffness of the second conductive layer.
20. The apparatus of clause 18, wherein a conductivity of the second conductive layer is in a range of about 50 S/cm to about 850 S/cm.
21. The apparatus of clause 18, wherein the second conductive layer comprises chromium nitride, titanium nitride, or carbon nitride.
22. The apparatus of clause 18, wherein a conductivity of the conductive layer is variable and configured to compensate for a conductivity of the second conductive layer such that a total conductivity of the apparatus is tuned to a desired value.
23. The apparatus of clause 1, wherein the cleaning apparatus is a reticle stage cleaning apparatus and the clamp is a reticle clamp.
24. A lithographic apparatus comprising the cleaning apparatus of any one of the preceding clauses.
25. A metrology apparatus comprising the cleaning apparatus of any one of the preceding clauses.
26. A lithographic apparatus comprising:
   an illumination system configured to illuminate a patterning device;
   a projection system configured to project an image of the patterning device onto a patterning substrate;
   a reticle stage configured to support the patterning device and comprising a chuck and an electrostatic clamp comprising a plurality of burls; and
   a reticle stage cleaning apparatus configured to dissipate charge on the electrostatic clamp and to remove particles on the electrostatic clamp, the reticle stage cleaning apparatus comprising:
      a substrate having a frontside and a backside opposite the frontside; and
   a conductive layer disposed on the frontside of the substrate and configured to contact the plurality of burls of the electrostatic clamp and to remove particles on the electrostatic clamp via an electrostatic field generated between the conductive layer and the electrostatic clamp.
27. The lithographic apparatus of clause 25, wherein the conductive layer comprises a conductive polymer.
28. The lithographic apparatus of clause 26, wherein the conductive polymer comprises polyaniline, poly-p-phenylene, polythiophene, polypyrrole, poly-p-phenylene vinylene, trans-polyacetylene, or a combination thereof.
29. A method of forming a reticle stage cleaning apparatus for removing particles on a reticle stage in a lithographic apparatus, the method comprising:
forming a conductive polymer on a frontside of a substrate with a conductivity of at least about 1 S/cm.
30. The method of clause 28, wherein the conductivity is at least about 10 S/cm.
31. The method of clause 28, wherein the conductivity is in a range between about 10 S/cm to about 600 S/cm.
32. The method of clause 28, wherein the conductive polymer comprises polyaniline, poly-p-phenylene, polythiophene, polypyrrole, poly-p-phenylene vinylene, trans-polyacetylene, or a combination thereof.
33. The method of clause 31, wherein a combination of polyaniline, poly-p-phenylene, polythiophene, polypyrrole, poly-p-phenylene vinylene, or trans-polyacetylene comprises polymer blends, copolymers, or grafted polymers.
34. The method of clause 28, wherein forming the conductive polymer comprises tuning the conductivity of the conductive polymer to a desired value.
35. The method of clause 33, wherein tuning the conductivity comprises using polymerization.
36. The method of clause 33, wherein tuning the conductivity comprises including an additive in the conductive polymer.
37. The method of clause 33, wherein tuning the conductivity comprises including a filler in the conductive polymer.
38. The method of clause 28, wherein forming the conductive polymer comprises spin coating, slit coating, dip coating, spray coating, electrospinning, deposition, gravure coating, or a combination thereof.
39. The method of clause 28, wherein forming the conductive polymer comprises forming a plurality of layers.
40. The method of clause 28, further comprising forming a conductive layer disposed between the conductive polymer and the substrate.
41. The method of clause 39, wherein forming the conductive polymer comprises tuning the conductivity of the conductive polymer based on a conductivity of the conductive layer such that a total conductivity of the reticle stage cleaning apparatus is tuned to a desired value.
42. The method of clause 39, wherein a stiffness of the conductive polymer is lower than a stiffness of the conductive layer.
43. The method of clause 28, wherein forming the conductive polymer comprises tuning a mechanical property of the conductive polymer to a desired value.
44. The method of clause 28, further comprising:
contacting the reticle stage cleaning apparatus with a plurality of burls of an electrostatic clamp of the reticle stage;
generating an electrostatic field between the reticle stage cleaning apparatus and the electrostatic clamp; and
removing particles disposed on the electrostatic clamp.
45. The method of clause 43, further comprising repeating the contacting, the generating, and the removing steps to further remove particles from the electrostatic clamp to the reticle stage cleaning apparatus.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track unit (a tool that typically applies a layer of resist to a substrate and develops the exposed resist), a metrology unit and/or an inspection unit. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of aspects in the context of optical lithography, it will be appreciated that aspects may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself may be patterned and materials added on top of it may also be patterned, or may remain without patterning.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

Although specific reference may be made in this text to the use of the apparatus and/or system in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific aspects have been described above, it will be appreciated that the aspects may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary aspects as contemplated by the inventor(s), and thus, are not intended to limit the aspects and the appended claims in any way.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

1. A cleaning apparatus for a clamp in a lithographic apparatus, the apparatus comprising:
a substrate having a frontside and a backside opposite the frontside; and
a conductive layer disposed on the frontside of the substrate and configured to contact the clamp to dissipate charge on the clamp and to remove particles on the clamp via an electrostatic field generated between the conductive layer and the clamp.

2. The apparatus of claim 1, wherein a conductivity of the conductive layer is at least about 1 S/cm, 10 S/cm, or 100 S/cm.

3. The apparatus of claim 1, wherein a conductivity of the conductive layer is in a range between about 1 S/cm to about 600 S/cm, 10 S/cm to about 600 S/cm, or 100 S/cm to about 600 S/cm.

4. The apparatus of claim 1, wherein a conductivity of the conductive layer is variable and configured to be tuned to a desired value.

5. The apparatus of claim 1, wherein the conductive layer comprises a conductive polymer.

6. The apparatus of claim 5, wherein the conductive polymer comprises polyaniline, poly-p-phenylene, polythiophene, polypyrrole, poly-p-phenylene vinylene, trans-polyacetylene, or a combination thereof.

7. The apparatus of claim 5, wherein:
the conductive polymer comprises an additive configured to modify a conductivity and/or a mechanical property of the conductive polymer; and
the additive comprises carbon, graphite, carbon black, carbon nanotubes, carbon fullerenes, metal particles, plasticizers, flame retardants, heat stabilizers, impact modifiers, antioxidants, colorants, lubricants, light stabilizers, quenchers, acid scavengers, pigments, antistatic agents, nucleating agents, tribological, slip compounds, or a combination thereof.

8. The apparatus of claim 5, wherein:
the conductive polymer comprises a filler configured to modify a conductivity and/or a mechanical property of the conductive polymer; and
the filler comprises an organic material, an inorganic material, a polymeric material, a metallic material, a ceramic material, or a combination thereof.

9. The apparatus of claim 5, wherein:
the conductive polymer comprises a single layer;
the conductive polymer comprises a plurality of layers; or
the conductive polymer comprises a surface treatment and/or a surface modification.

10. The apparatus of claim 1, further comprising a second conductive layer disposed between the conductive layer and the substrate, wherein:
a stiffness of the conductive layer is lower than a stiffness of the second conductive layer;
a conductivity of the second conductive layer is in a range of about 50 S/cm to about 850 S/cm;
the second conductive layer comprises chromium nitride, titanium nitride, or carbon nitride; and
a conductivity of the conductive layer is variable and configured to compensate for a conductivity of the second conductive layer such that a total conductivity of the apparatus is tuned to a desired value.

11. The apparatus of claim 1, wherein the cleaning apparatus is a reticle stage cleaning apparatus and the clamp is a reticle clamp.

12. A lithographic apparatus comprising:
an illumination system configured to illuminate a patterning device;
a projection system configured to project an image of the patterning device onto a patterning substrate;
a reticle stage configured to support the patterning device and comprising a chuck and an electrostatic clamp comprising a plurality of burls; and
a reticle stage cleaning apparatus configured to dissipate charge on the electrostatic clamp and to remove particles on the electrostatic clamp, the reticle stage cleaning apparatus comprising:
a substrate having a frontside and a backside opposite the frontside; and
a conductive layer disposed on the frontside of the substrate and configured to contact the plurality of burls of the electrostatic clamp and to remove particles on the electrostatic clamp via an electrostatic field generated between the conductive layer and the electrostatic clamp.

13. A method of forming a reticle stage cleaning apparatus for removing particles on a reticle stage in a lithographic apparatus, the method comprising:
forming a conductive polymer on a frontside of a substrate with a conductivity of at least about 1 S/cm.

14. The method of claim 13, further comprising:
contacting the reticle stage cleaning apparatus with a plurality of burls of an electrostatic clamp of the reticle stage;
generating an electrostatic field between the reticle stage cleaning apparatus and the electrostatic clamp; and
removing particles disposed on the electrostatic clamp.

15. The method of claim 14, further comprising repeating the contacting, the generating, and the removing steps to further remove particles from the electrostatic clamp to the reticle stage cleaning apparatus.
